(19) United States
(12) Patent Application Publication
(10) Pub. No.: US 2005/0014308 A1
(43) Pub. Date: Jan. 20, 2005

(54) Manufacturing process of memory module with direct die-attachment

(76) Inventors: Yuan-Ping Tseng, Chiunglin Shiang (TW); An-Hong Liu, Tainan City (TW); Y. J. Lee, Rende Shiang (TW)

Correspondence Address: BIRCH STEWART KOLASCH & BIRCH, PO BOX 747, FALLS CHURCH, VA, 22040-0747, US

(21) Appl. No.: 10/620,446

(22) Filed: Jul. 17, 2003

(51) Int. Cl. H01L 21/44; H01L 21/48; H01L 21/50

(52) U.S. Cl. 438/106; 438/127

(57) ABSTRACT

A manufacturing process of memory module with direct die-attachment is provided to integrate the process of packaging, module assembling and testing. When a plurality of memory chips are singulated from a wafer, a determined amount of the memory chips are directly mounted to a module substrate, and electrically connected to gold fingers of the module substrate. The module substrate mounting the memory chips is loaded in a memory module tester. The memory chips are tested to verify their electrical performance by contacting the gold fingers, and then the bad ones are repaired or replaced before packaging the memory chips. The manufacturing process of memory module with direct die-attachment can reduce the investment of testers and also the cost of testing.

### FIELD OF THE INVENTION

The present invention relates to a manufacturing process of a memory module and, more particularly, to a manufacturing process of memory module with direct die-attachment which integrates the processes of testing and packaging on a module substrate.

### BACKGROUND OF THE INVENTION

The conventional way of manufacturing memory module mainly divided into three procedures, that is, the wafer fabrications, assemble and testing, and module assembly and testing. Usually, memory wafers are provided by a wafer FAB. After wafers are tested and repaired by laser radiation, they are handled by an assemble house to be singulated as dices and then bonded and electrically connected to an IC carrier, such as lead frames, substrates or tapes, and sealed by molding compounds or other materials (such as underfill material) to become an IC component in a package, such as Thin Small Outline Package (TSOP), Ball Grid Array Package (BGA), etc. The package will go through functional test and/or burn-in test to verify their electrical performance. Thereafter, the separated packages are mounted on a module board, such as small strip printed circuit boards, to assemble as a memory module by a module house and then proceeding to a memory module test. As for the conventional standard procedure, each fabrication of memory module needs to go through three different testers, that is, the wafer tester, the package tester and the module tester. Although the testers mentioned above are all for memory testing, yet the probe card for the wafer tester, the HI-FIX for the package tester, and the socket board for the module tester are quite different tooling with different functions and can not be integrated. Therefore, it needs three costly testers in the manufacturing process of each memory module that results in a sky-high tester investment.

Memory module is developing toward low unit price and high memory capacity. While continuing researching and developing in the high capacity, high-density memory wafer, it also needs to effectively reduce the cost in manufacturing memory module, especially the cost in wafer fabrication, testing and assemble and module assembly and testing. FIG. 1 refers to conventional manufacturing steps of memory module with direct die-attachment. Firstly, a memory wafer is provided in step 11 of “providing a wafer”, then going to next step “first wafer-level testing” 12, “burn-in testing” 13, and “second wafer-level testing” 14 in wafer form. Then, according to the testing result of the second wafer-level testing 14, the wafer is selectively singulated in step 15 of dicing-wafer as a plurality of chip modules 20, as shown in FIG. 2. Each chip module 20 is formed as a unit by an array of a plurality of memory chips 21, which are fabricated with a plurality of bumps 22. After step 16 of providing a module substrate, the chip module 20 is directly attached to a module substrate 30 in step 17. In packaging step 18, the bumps 22 are protected with an underfilling material 40. Even though the above manufacturing processes of memory module with direct die-attachment has integrated chip assembling process with the module assembling process, however, some problems still remain. The testing steps of 12 and 14 refer to the wafer-level testing, they can not provide effective testing for the electrical performance between the chip module 20 and the module substrate 30. When the attached chip module 20 after the step 17 has a failed chip 21 on it which is impossible to repair or replace the failed chip 21a on the module substrate 30. The other problem that needs attention is the manufacturing of chip module 20. After a wafer is fabricated, it is selectively, singulated according to the test outcome of wafer testing to form a chip module 20 with a plurality of chips 21. Each time the path of wafer dicing is different, which not only makes it more difficult to manufacture a chip module as a whole, but also makes it more complex and difficult to the automation for wafer dicing. For example, a bad chip can be located at any places on a wafer which make the manufacturing of chip module 20 as a whole more difficult. Moreover, the chip module 20, which has a much larger surface area than that of conventional individual memory chips, will encounter a greater stress from thermal mismatch while attached to the module substrate 30 which makes it more easily to be stripped or warped.

### SUMMARY OF THE INVENTION

A main purpose of the present invention is to supply a manufacturing process of memory module with direct die-attachment. After a wafer is singulated, a plurality of memory chips are directly attached to a module substrate then at least a module-level testing is performed to repair or replace the bad chips on the module substrate before packaging, thus to reduce the cost of installation of tester and the cost of testing. This module-level testing process helps to confirm the electrical performance of the memory chips with the module substrate and also the function of module substrate.

A second purpose of the present invention is to supply a manufacturing process of memory module with directly die-attachment. A plurality of memory chips are tested on a module substrate. A bad memory chip on the module substrate can be repaired by laser radiation or replaced by a known good die (KGD) before packaging. This will integrate wafer-level testing and package-level testing into a module-level testing and reduce the overall testing cost.

The manufacturing process of memory module with direct die-attachment according to the present invention comprises the following steps of: providing a wafer with a plurality of memory chips; singulating the wafer to form a plurality of memory chips; providing a module substrate with a plurality of gold fingers; attaching a predetermined amount of memory chips on the module substrate and electrically connecting to the gold fingers; performing a first module-level testing through the gold fingers for testing the memory chips on the module substrate; and packaging the memory chips on the module substrate. It is preferable that a burn-in testing at the wafer-level or module-level is included.

### DESCRIPTION OF THE DRAWINGS

FIG. 1 is a flow chart of a conventional manufacturing process of memory module with direct die-attachment;

FIG. 2 is a cross-sectional view of a conventional memory module with direct die-attachment;

FIG. 3 is a flow chart of a manufacturing process of memory module with direct die-attachment in accordance with the first embodiment of the present invention;

FIG. 4 is a top view of a module substrate in accordance with the first embodiment of the present invention;

FIG. 5A is a cross-sectional view of a module substrate with attached memory chips in the die-attaching step in accordance with the first embodiment of the present invention;

FIG. 5B is a cross-sectional view of a memory module with direct die-attachment in the first module-level testing step in accordance with the first embodiment of the present invention;

FIG. 5C is a cross-sectional view of a memory module with direct die-attachment in a first repairing step in accordance with the first embodiment of the present invention;

FIG. 5D is a cross-sectional view of a memory module with direct die-attachment in a second repairing step in accordance with the first embodiment of the present invention;

FIG. 5E is a cross-sectional view of a memory module with direct die-attachment in the second module-level testing step in accordance with the first embodiment of the present invention;

FIG. 5F is a cross-sectional view of a memory module with direct die-attachment in the packaging step in accordance with the first embodiment of the present invention;

FIG. 6 is a front view of a memory module with direct die-attachment of the element disassembly in accordance with the second embodiment of the present invention;

FIG. 7 is a cross-sectional view of a memory module with direct die-attachment in accordance with the second embodiment of the present invention; and

FIG. 8 is a cross-sectional view of a memory module with direct die-attachment in the module-level testing step before packaging in accordance with the second embodiment of the present invention

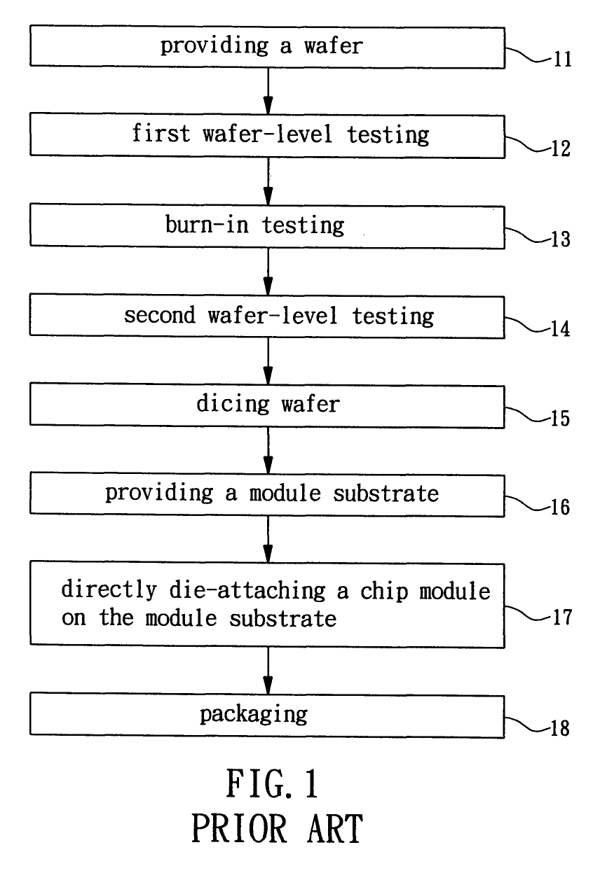

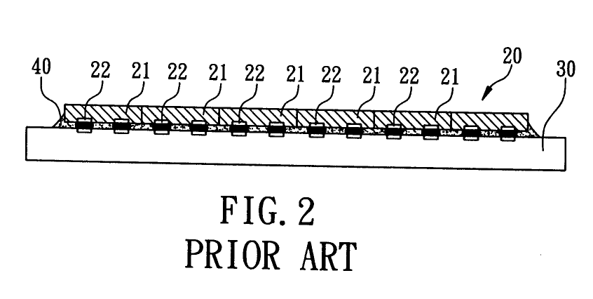

### DETAIL DESCRIPTION OF THE INVENTION

Please refer to the drawings attached, present invention will be described by means of an embodiment below.

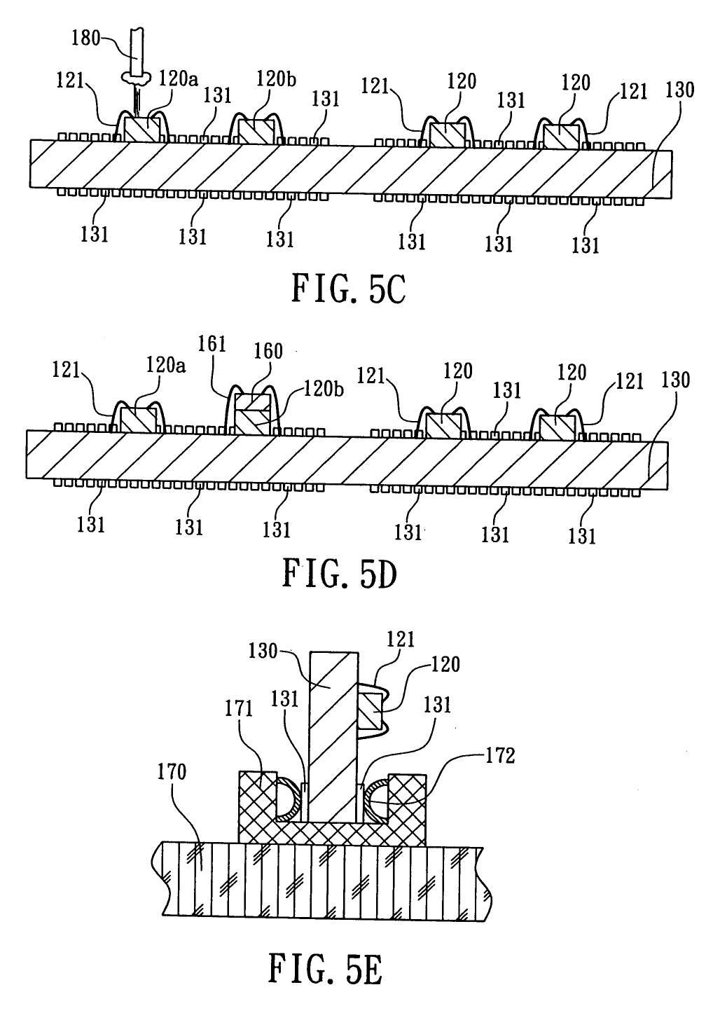

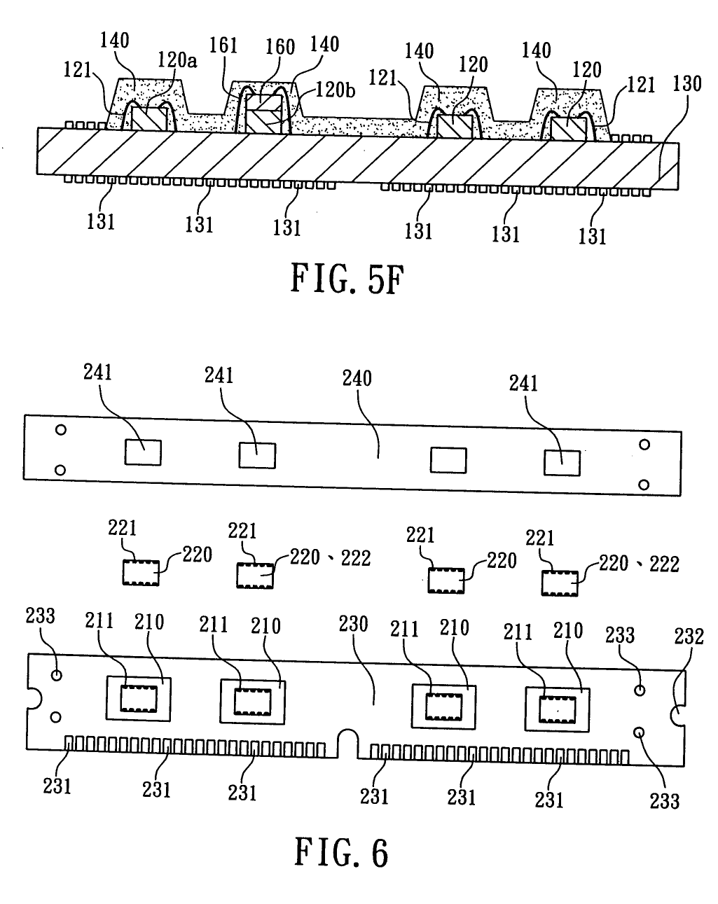

In accordance with the first embodiment of the present show as FIG. 5F, a memory module with direct die-attachment comprise a module substrate 130 and a plurality of memory chips 120, 120a, 120b. The module substrate 130 is connecting with the memory chips 120, 120a and 120b by bonding wires 121, TAB (Tape Automated Bonding) leads or bumps. The memory chips 120, 120a and 120b electrically connect to corresponding gold fingers 131 of the module substrate 130. Besides, the memory module with direct die-attachment also comprises at least an encapsulating material 140 joining the memory chips 120 120a, 120b on the module substrate 130.

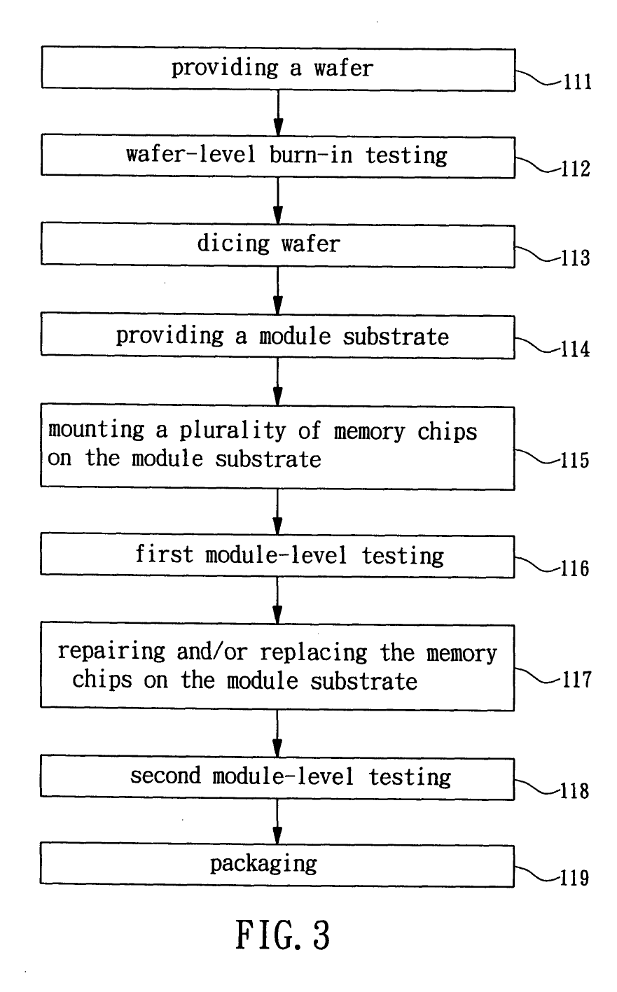

FIG. 3 refers to the manufacturing process of memory module with direct die-attachment in accordance with the present invention. In first embodiment, the process comprises the following steps: step 111 of “providing a wafer”, step 112 of “wafer-level burn-in testing”, step 113 of “dicing wafer ”, step 114 of “providing a module substrate”, step 115 of “mounting a plurality of memory chips on the module substrate”, step 116 of “first module-level testing”, step 117 of “repairing and/or replacing the memory chips on the module substrate”, step 118 of “second module-level testing”, and a packaging step 119. In the wafer-providing step 111, a wafer having a plurality of memory chips is provided (not shown in figure). It is preferable that to perform the step 112 of “wafer-level burn-in testing” after the step 111. The burn-in test is performed under the temperature of 125˜150° C., and applied with a higher voltage than that of a normal functioning memory chip, which is higher than 2.5V, for example, to screen out all the possible early failure chips. Then, a plurality of individual memory chips 120, 120a and 120b are manufactured by singulating the wafer in the step 113 of “dicing wafer”.

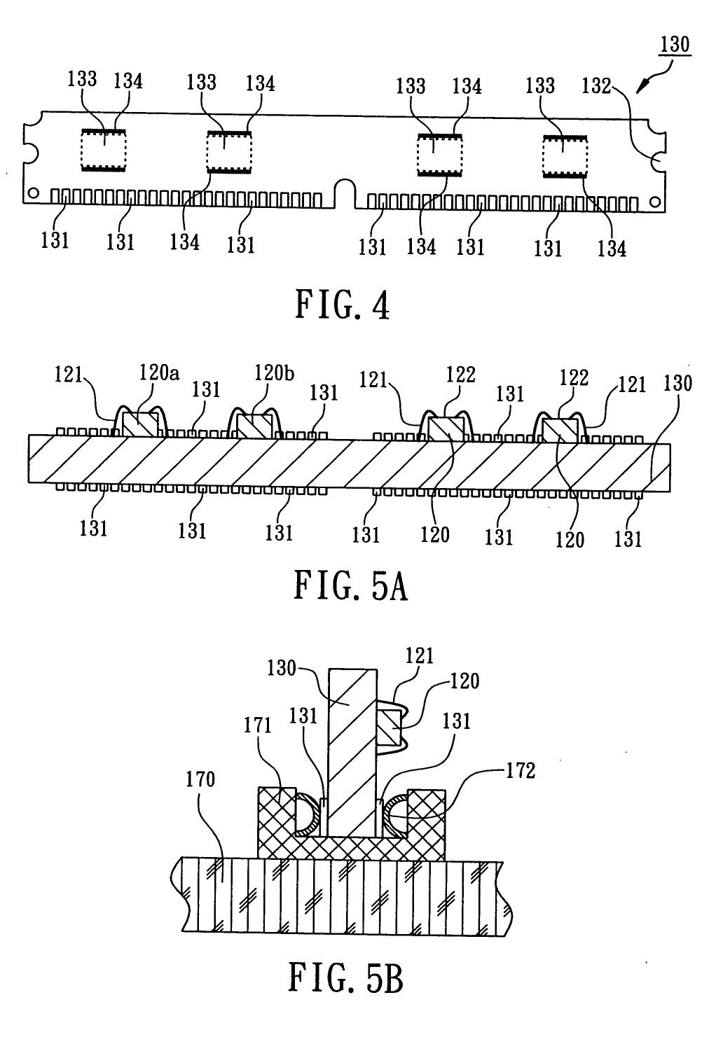

As shown in FIG. 4, in the step 114 of “providing a module substrate”, the provided module substrate 130 is a printed circuit board or a plastic board in strip form. The module substrate 130 used in the DRAM memory module is a printed circuit board with multi-layer circuits, about 4 to 8 layers or even more. The gold fingers 131 are formed on one side of the module board 130 for outer electrical connection, such as connecting to a mother board of computer. In this embodiment, the module substrate 130 is Double Data Rate Dual In-line Memory Module (DDR DIMM), with 184 gold fingers 131. Yet in this embodiment, type of the module substrate 130 and numbers of gold fingers 131 are not limited, and the module substrate 130 also can be SDRAM, DDR DRAM, Rambus DRAM, SRAM, flash or other module substrate. The module substrate 130 can be formed with a locking slot 132 on two narrower sides, to fix and position while plugging in. The module substrate 130 also has a plurality of die-attach areas 133 for attaching memory chips 120. In this embodiment, there are a plurality of connecting pads 134 around each die-attaching areas 133, which are electrically connected with the gold fingers 131 via the internal circuits of the module substrate 130.

In the chip-mounting step 115, as shown in FIG. 5A, a predetermined numbers (such as 2, 4, 8, 16, 32 or amount) of memory chips 120, 120a and 120b singulated from the wafer are attached to the die-attach areas 133 of the module substrate 130. In this embodiment, the back sides of memory chips 120 are adhered to the module substrate by die attach adhesive, such as silver paste or polyimide tape, so that the active surfaces 122 of memory chips 120, 120a and 120b can be faced up. The memory chips 120, 120a and 120b are electrically connected to the connecting pads 134 of module substrate 130 by a plurality of bonding wires 121 or TAB leads. Afterward, the step 116 of “first module-level testing” is performed. As shown in FIG. 5B, the module substrate 130 mounting the memory chips 120, 120a and 120b is loaded in a memory module tester for going through the first module-level testing. The memory module tester has a testing board 170 with slot socket 171. When the module substrate 130 is inserted in the slot socket 171, the gold fingers 131 of the module substrate are contacted and electrically connected to contact terminals 172 of the socket 171 so as to electrically connect to the module tester, and then performs electrical testing on the memory chips 120, 120a and 120b to acquire data of good/repairable/bad chips from this module-level testing. Besides, a tester with a probe card also can be used in the module-level testing except memory module tester with sockets. After the step 116 of first module-level testing, it proceeds to the step 117 to repair and/or to replace the memory chips 120, 120a and 120b on the module substrate 130. The memory chips 120a, 120b and 120 attached on the module substrate 130 are repaired according to the testing results of the first module-level testing in step 116. As shown in FIG. 5C, when a repairable chip 120a is detected according to the result of Memory Repair Analysis (MRA), and after the chip 120a being positioning, the fuse link of memory chip 120a is radiated by a laser equipment 180 or blown by a high electrical current. The redundant circuits in memory chip 120a are used to replace the damaged memory circuits. As shown in FIG. 5D, when a chip 120b, which is bad and can not be repaired, is detected, the chip 120b is replaced by another memory chip 160 and electrically connected to the module substrate 130 by bonding wires 161 or other electrical connection devices. It is preferable that the chip 160 is a Known Good Die (KGD). Preferably, it is to perform the step 118 of “second module-level testing” after the step 117. As shown in FIG. 5E, the module substrate 130 will go through a module-level testing by a memory module tester, which may be a same tester used in the step 116. The module substrate 130 is inserted in the socket 171 of the testing board 170 so that the gold finger 131 are contacted and electrically connected to the contact terminals 172 of the socket 171, to confirm module quality and for speed sorting. Finally, it proceeds to the packaging step 119. As shown in FIG. 5F, the encapsulating material 140 is formed on the module substrate 130 by molding, stenciling or potting in order to protect the memory chips 120a, 120 and 160. In this embodiment, the encapsulating material 140 seals and joints the memory chips 120a, 120 and 160.

Therefore, the manufacturing process of memory module with direct die-attachment according to the present invention effectively integrates the procedures of packaging, module assembling and testing, and also minimizes the investment of wafer-level testers, package-level testers and module-level testers. The step 116 and 118 of module-level testing ensures good electrical connection between the chips 120 and module substrate 130. Therefore, the manufacturing processes according to the present invention will contribute to reduce manufacturing cost and provide high quality products.

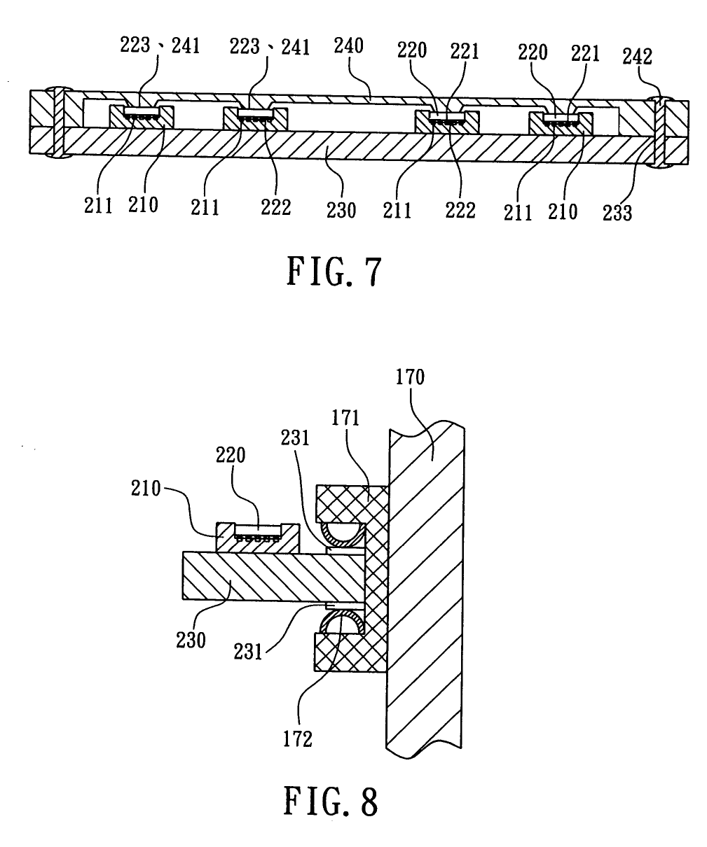

The second embodiment in accordance with the present invention please refer to FIGS. 6 and 7. Firstly, in the step 114, a provided module substrate 230 has a plurality of gold fingers 231 and locking slots 232. The die-attaching areas of module substrate 230 are fixed with a plurality of chip-mounting sockets 210, and each chip-mounting socket 210 has a plurality of contact ends 211 electrically connected to the gold fingers 231 of the module substrate 230 for contacting a plurality of memory chips 220. A predetermined amount of memory chips 220 (such as 2, 4, 8, 16, 32 or other amount) are provided. Each memory chip 220 has an active surface 222 and a corresponding back surface 223. The active surface 222 is formed with a plurality of electrodes 221, such as bumps or bonding pads. With the active surface 222 facing toward the module substrate 230, the memory chips 220 are mounted to the chip-mounting sockets 210 on module substrate 230 in plug-in and pull-away type and the electrodes 221 of memory chips 220 are electrically connected to the contact ends 211 of the corresponding chip-mounting sockets 210 in the step 115. Thereafter, the step 116 of “first module-level testing” is executed. The module substrate 230 attached with memory chips 220 go through the module-level testing step 116 by a memory module tester. As shown in FIG. 8, when the memory module substrate 230 is plugged in the socket 171 of the testing board 170, the gold fingers 231 of module substrate 230 are electrically connected to the module tester, which tests the memory chips 220 on module substrate 230 via the electrical contact of the gold fingers 231. When a bad memory chips are detected, it is taken out from the chip-mounting sockets 210 on memory module substrate 230 and replaced by a known good die memory chip. After the repairing step 117, it proceeds to the step 118 of second module-level testing. Finally, in the packaging step 119, a metal shield 240 is installed on the module substrate 230. The metal shield 240 is combined with the module substrate 230 with fixtures 242 jointing with fixing holes 233 on module substrate 230 for sealing the memory chips 220. The metal shield 240 has a plurality of compressible surfaces 241, which compress the back surface 223 of the memory chips 220, to improve heat dissipation and stability of the memory chips 220.

Therefore, the manufacturing process of memory module with direct die-attachment according to the present invention effectively integrates the procedures of package, module-assembly and testing. The module-level testing through contacting the gold finger of the module substrate ensures good electrical connection between the chips 220 and module substrate 230 by low cost module tester, and it is applicable to repair the repairable memory chips on the module substrate 230.

The above description of embodiments of this invention is intended to be illustrative and not limiting. Other embodiments of this invention will be obvious to those skilled in the art in view of the above disclosure.

1. A manufacturing process of memory module with directly die-attachment comprising the following steps of:
providing a wafer, the wafer containing a plurality of memory chips;
dicing the wafer to form a plurality of individual memory chips;
providing a module substrate, the module substrate having a plurality of gold fingers for outer connection;
mounting a predetermined amount of the memory chips on the module substrate and electrically connected with the gold fingers of the module substrate;
performing a first module-level testing to test the memory chips on the module substrate; and
packaging the memory chips on the module substrate.

2. The manufacturing process of memory module with direct die-attachment of claim 1, wherein the gold fingers of the module substrate are contacted for module-level testing the memory chips on the module substrate.

3. The manufacturing process of memory module with direct die-attachment of claim 1, further comprising a step of: repairing the memory chips on the module substrate according to the testing results of first module-level testing prior to the packaging step.

4. The manufacturing process of memory module with direct die-attachment of claim 3, further comprising a step of: performing a second module-level testing to test the memory chips attached on the module substrate after the repairing step.

5. The manufacturing process of memory module with direct die-attachment of claim 3, wherein at least a bad memory chip is replaced with another memory chip during the repairing step.

6. The manufacturing process of memory module with direct die-attachment of claim 5, wherein the replacing memory chip is a known good die (KGD).

7. The manufacturing process of memory module with direct die-attachment of claim 3, wherein at least a bad chip yet still repairable memory chip on module substrate is repaired by laser radiation during the repairing step.

8. The manufacturing process of memory module with direct die-attachment of claim 1, wherein an encapsulating material is formed to join the memory chips on the module substrate in the packaging step.

9. The manufacturing process of memory module with direct die-attachment of claim 8, wherein the encapsulating material seals the memory chips.

10. The manufacturing process of memory module with direct die-attachment of claim 1, wherein a metal shield is combined with the module substrate for protecting and thermally dissipating the memory chips in the packaging step.

11. The manufacturing process of memory module with direct die-attachment of claim 10, wherein the metal shield is attached to the memory chips on the module substrate.

12. The manufacturing process of memory module with direct die-attachment of claim 1, wherein the module substrate has a plurality of chip-mounting sockets for mounting the memory chips.

13. The manufacturing process of memory module with direct die-attachment, comprising the following steps:
providing a module substrate, the module substrate having a plurality of gold fingers at one side;
mounting a plurality of memory chips on the module substrate, each memory chip having a plurality of electrodes electrically connecting with the gold fingers of the module substrate;
performing a module-level testing to test the memory chips on the module substrate by contacting the gold fingers of the module substrate; and
packaging the memory chips on the module substrate after the module-level testing.

14. The manufacturing process of memory module with direct die-attachment of claim 13, further comprising a step of: repairing the memory chips on the module substrate according to the testing results of the module-level testing.

15. The manufacturing process of memory module with direct die-attachment of claim 13, wherein the module substrate has a plurality of chip-mounting sockets for mounting the memory chips.

16. The manufacturing process of memory module with direct die-attachment of claim 13, wherein an encapsulating material is formed to join the memory chips in the packaging step.

17. The manufacturing process of memory module with direct die-attachment of claim 13, wherein a metal shield is combined with the module substrate for protecting and thermally dissipating the memory chips in the packaging step.
